(19) United States
(12) Patent Application Publication
(10) Pub. No.: US 2009/0079455 A1
(43) Pub. Date: Mar. 26, 2009

(54) REDUCED SCRUB CONTACT ELEMENT

(75) Inventor: John K. Gritters, Livermore, CA (US)

Correspondence Address: MOSER IP LAW GROUP / FORMFACTOR, INC., 1030 BROAD STREET, 2ND FLOOR, SHREWSBURY, NJ, 07702, US

(73) Assignee: FORMFACTOR, INC., Livermore, CA (US)

(21) Appl. No.: 11/862,172

(22) Filed: Sep. 26, 2007

(51) Int. Cl. G01R 31/306; H01R 12/16; H01R 43/00

(52) U.S. Cl. 324/762; 29/874; 29/884; 439/81

(57) ABSTRACT

Embodiments of resilient contact elements and methods for fabricating and using same are provided herein. In one embodiment, a resilient contact element includes a lithographically formed resilient beam having a plurality of openings disposed laterally therethrough; and a tip disposed proximate a first end of the beam, the tip and the beam together configured to electrically probe a device to be tested.

### BACKGROUND OF THE INVENTION

1. Field of the Invention

Embodiments of the present invention generally relate to resilient contact elements and more specifically, to resilient contact elements used in testing of semiconductor devices.

2. Description of the Related Art

Testing is an important step in the fabrication of semiconductor devices. Typically, partially or fully completed semiconductor devices are tested by bringing terminals disposed on an upper surface of a device to be tested—also referred to as a device under test (or DUT)—into contact with resilient contact elements, for example, as contained in a probe card assembly, as part of a test system. However, as the size of features formed on the DUT continue to be reduced (for example, to 70 microns and below) problems arise with the scalability of the resilient contact elements on the probe card. Specifically, a corresponding reduction in size of the resilient contact elements to facilitate contacting smaller test features (e.g., bond pads or test pads) on the DUT increases the incidence of scrubbing off the contacting feature or buckling and/or alignment problems with the resilient contact elements. Moreover, the reduction in size of the resilient contact elements generally increases the scrub, or scrub ratio, of the resilient contact element. The increased scrub/scrub ratio restricts the over-travel budget required to establish proper electrical contact with one or more terminals of the DUT without the resilient contact element scrubbing off at least some of the DUT contacts during probing. Moreover, multi-DUT testing with multiple resilient contact elements may require even greater probe over-travel to overcome non-planarity across the probing area to achieve simultaneous contact of all resilient contact elements.

Therefore, there is a need for an improved resilient contact element suitable for use in testing devices having smaller feature sizes.

### SUMMARY OF THE INVENTION

Embodiments of resilient contact elements and methods for fabricating and using same are provided herein. In some embodiments, a resilient contact element includes a lithographically formed resilient beam having a plurality of openings disposed laterally therethrough; and a tip disposed proximate a first end of the beam, the tip and the beam together configured to electrically probe a device to be tested.

In some embodiments, a probe card assembly for testing a semiconductor device includes a probe substrate; and at least one resilient contact element coupled to the probe substrate, the resilient contact element including a lithographically formed resilient beam having a plurality of openings disposed laterally therethrough; and a tip disposed proximate a first end of the beam, the tip and the beam together configured to electrically probe a device to be tested.

In some embodiments, the invention provides a method of fabricating a resilient contact element for use in testing a device. In some embodiments, a method of fabricating a resilient contact element includes a) forming a lower layer of a beam upon a substrate; b) forming one or more regions of sacrificial material atop one or more portions of the lower layer of the beam to define one or more covered regions of the lower layer and one or more exposed regions of the lower layer; c) forming an upper layer of the beam atop the one or more exposed regions of the lower layer and the one or more covered regions of the lower layer to define the beam; and d) removing the one or more regions of sacrificial material to create one or more openings disposed laterally through the beam.

In some embodiments, the invention provides a method of testing a device. In some embodiments, a method of testing a device includes providing a probe card assembly comprising a probe substrate having a plurality of resilient contact elements coupled thereto, at least one resilient contact element comprising a lithographically formed resilient beam having a plurality of openings disposed laterally therethrough, and a tip disposed proximate a first end of the beam, the tip and the beam together configured to electrically probe a device to be tested; and contacting a plurality of terminals of the device with the tips of respective resilient contact elements.

In some embodiments, the invention provides a semiconductor device that has been tested by methods of the present invention. In some embodiments, a semiconductor device is provided that is tested by a method including providing a probe card assembly comprising a probe substrate having a plurality of resilient contact elements coupled thereto, at least one resilient contact element comprising a lithographically formed resilient beam having a plurality of openings disposed laterally therethrough, and a tip disposed proximate a first end of the beam, the tip and the beam together configured to electrically probe a device to be tested; and contacting a plurality of terminals of the device with the tips of respective resilient contact elements.

### BRIEF DESCRIPTION OF THE DRAWINGS

So that the manner in which the above recited features of the present invention can be understood in detail, a more particular description of the invention, briefly summarized above and others described below, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a perspective view of one embodiment of a resilient contact element according to some embodiments the invention.

FIG. 2 depicts a flow chart of a method of fabricating a resilient contact element according to some embodiments of the invention.

FIGS. 3A-F depict schematic side views of stages of fabrication of a resilient contact element according to some embodiments the invention.

FIGS. 4A-E depict schematic side views of stages of fabrication of a resilient contact element according to some embodiments the invention.

FIG. 5 depicts a schematic side view of a probe card assembly having a resilient contact element according to some embodiments of the invention.

FIG. 6 depicts a flow chart of a method of testing a device according to some embodiments of the invention.

FIGS. 7A-C depict partial front views of variants of tips of the resilient contact element of FIG. 1 in accordance with some embodiments of the invention.

FIGS. 8A-B depict top views of variants of the resilient contact element of FIG. 1 in accordance with some embodiments of the invention.

FIG. 9 depicts a schematic top view of an array of resilient contact elements in accordance with some embodiments of the invention.

Where possible, identical reference numerals are used herein to designate identical elements that are common to the figures. The images used in the drawings are simplified for illustrative purposes and are not necessarily depicted to scale.

### DETAILED DESCRIPTION

The present invention provides methods and apparatus suitable for testing devices having reduced contact feature sizes (e.g., under 50 microns). The inventive apparatus and methods can facilitate testing of such devices with reduced scrub (or scrub ratio), which may reduce the incidence of mis-probes by maintaining better alignment with and contact to the devices. It is contemplated that the inventive apparatus and methods may also be used to advantage in testing devices having larger feature sizes as well. The reduced scrub may further advantageously reduce damage to the probing pad area on the DUT.

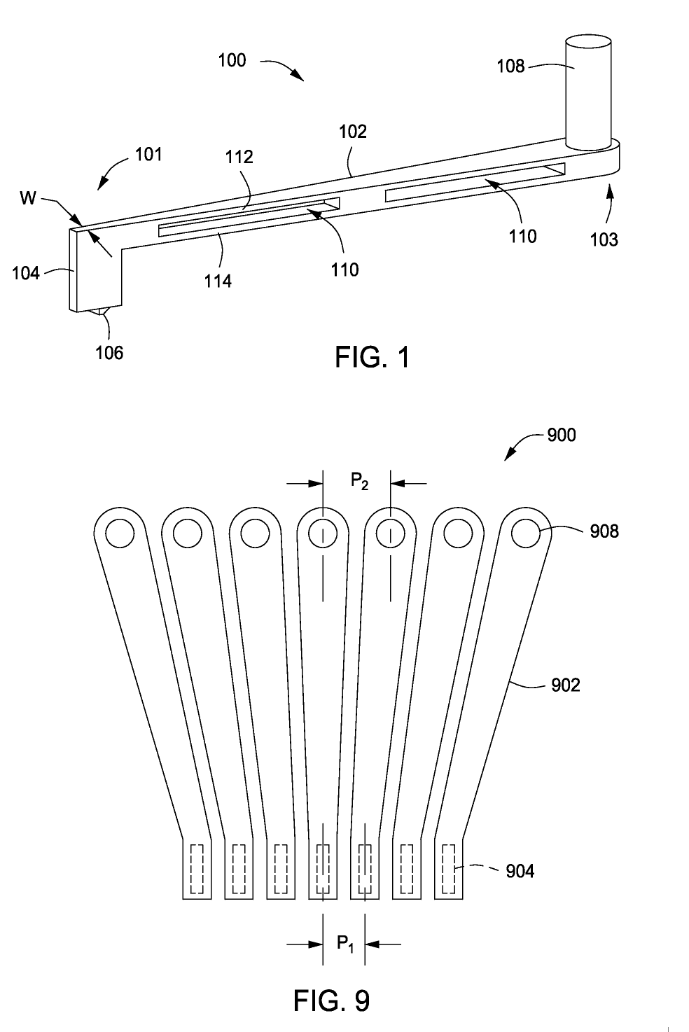

FIG. 1 depicts a perspective view of one embodiment of a resilient contact element 100 according to some embodiments the present invention. The resilient contact element 100 generally includes a beam 102 having one or more openings (e.g., slots) 110 disposed laterally therethrough (two openings 110 are illustratively shown in FIG. 1) and a tip 104 disposed proximate a first end 101 of the beam 102.

The beam 102 may comprise one or more layers and may comprise one or more electrically conductive and/or nonconductive materials. Examples of suitable conductive materials include metals. In some embodiments, the beam 102 may comprise nickel, copper, cobalt, iron, gold, silver, elements of the platinum group, noble metals, semi-noble metals, elements of the palladium group, tungsten, molybdenum, beryllium, and the like, and alloys thereof (such as nickel-cobalt alloys, copper-beryllium alloys, and the like).

The openings 110 may generally have any size or geometry. In some embodiments, the openings 110 are substantially rectangular. The openings 110 may be vertically centered or vertically offset with respect to a thickness T of the beam 102, such that the respective thicknesses of an upper portion 112 of the beam 102 disposed above the opening 110 and a lower portion 114 of the beam 102 disposed below the opening 110 may be substantially equal or may be different. In some embodiments, the openings 110 are vertically centered, thereby evenly distributing forces existing during deflection of the beam 102 and advantageously limiting the risk of buckling of the upper or lower portions 112, 114 of the beam 102. In embodiments where a plurality of openings 110 are provided, the openings 110 may be configured identically or different from each other.

The lateral openings 110 may advantageously reduce the scrub length of the resilient contact element 100 during operation. The scrub length of a contact element is the forward distance that the tip moves after contacting the surface of the DUT as the result of continued compression. This is sometimes referred to as the scrub ratio when dividing the forward distance moved by the tip by the downward distance moved by the contact element after initial contact with the DUT. In some embodiments of the present invention, the scrub length of the surface of the DUT (or scrub ratio) may advantageously be reduced due to the openings 110 disposed laterally through the beam 102. Moreover, the resilient contact element 100 may further utilize a taller tip 104 (i.e., a tip having a greater distance from the beam) while minimizing the undesired associated increase in scrub distance resultant from a similar increase in tip length of a conventional cantilevered contact element. In addition, the reduced scrub of the resilient contact elements 100 further can facilitate closer spacing of the resilient contact elements 100 to each other or to other components (e.g., in head to head, or linear, layout configurations), as compared to other cantilevered contact elements not configured as described herein. This can facilitate higher packing density of components and contact elements on a given substrate. In some embodiments, resilient contact elements configured with the openings 110 may advantageously provide a widened temperature range for dual temperature testing operations by minimizing the contribution of the resilient contact element to touchdown performance (e.g., by having a shortened scrub length, the probability of scrubbing off a contact pad is reduced for a given range of thermally induced motion of the contact pads and/or contact elements, which may facilitate using a wider range of temperatures).

The width, W, of the beam 102 may be uniform or may vary along the length of the beam 102. In some embodiments, the width W may be greater proximate the second end 103 of the beam 102 and may gradually taper towards the first end 101 of the beam 102. In some embodiments, the width, W, may vary along the length of the beam 102.

The beam 102 typically has a spring constant and yield strength suitable for developing sufficient contact force when contacting a DUT (e.g., sufficient to establish a reliable, temporary electrical contact with a terminal of the DUT) and for repeated contacting of DUT contact elements without permanent deformation. In some instances a plurality of the beams across a probing surface may be compliant enough to allow sufficient overtravel to facilitate suitably contacting a plurality of contact elements to the DUT, which may be at different heights or wherein the tips may be at different heights. Overtravel refers to the continued movement of the DUT towards the probe card assembly after the initial contact of the first resilient contact element to contact the DUT due to one or both of the non-planarity of the respective tips of the resilient contact elements disposed on the probe card assembly and variations in the heights of the terminals of the DUT. In a non-limiting exemplary range, the amount of overtravel may be between about 1-4 mils (about 25.4-102 μm). In some embodiments, the beam 102 may have a spring constant in a non-limiting exemplary range of between about 0.2-5 grams force per mil of movement. In some embodiments, the contact force developed during testing may be less that about 5 grams force, or in some embodiments between about 0.2-5 grams force. It is contemplated that the beam 102 may have other spring constants for applications where lesser or greater contact forces are required to establish reliable temporary electrical contact with the DUT without damaging either the resilient contact element or the DUT. Moreover, it is contemplated that as dimensions of the features being tested on a DUT continue to shrink, the specific dimensions, spring constants, overtravel requirements, and the like for the resilient contact element 100 may change while still remaining within the scope of this invention.

The spring constant and performance of the beam 102, and thereby the resilient contact element 100, may be selectively controlled for a particular application by the design of the beam 102 and/or selection of materials comprising the beam 102. For example, the number and geometry of the openings 110 may be selected to facilitate control of the spring constant of the resilient contact element 100 and/or performance characteristics of the resilient contact element 100. In some embodiments, the lateral openings 110 may be further configured to advantageously reduce the probability of buckling and/or misalignment of the resilient contact element 100 during operation, as discussed above.

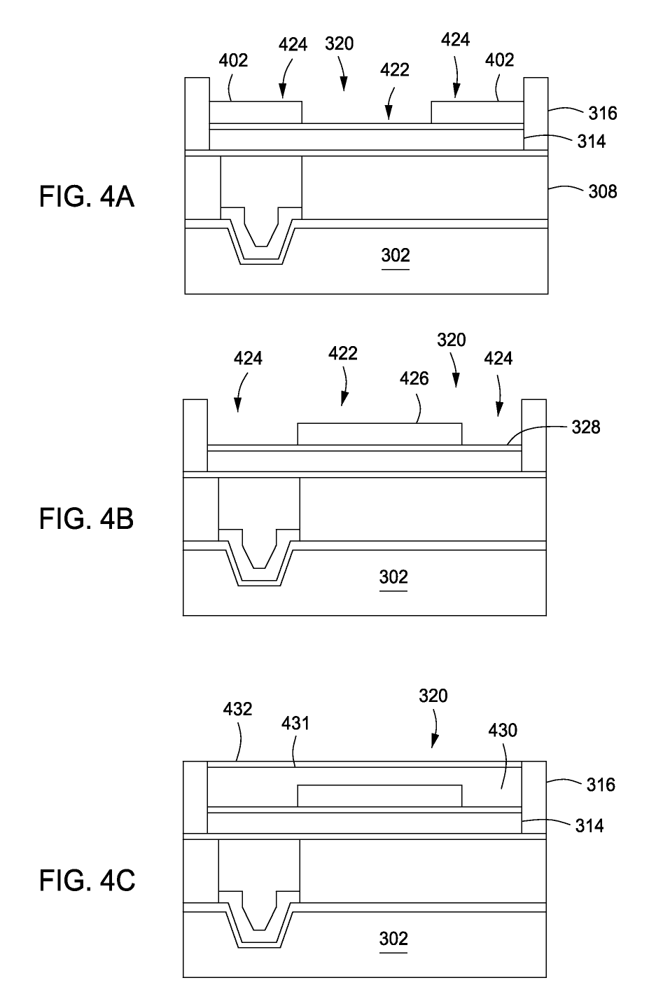

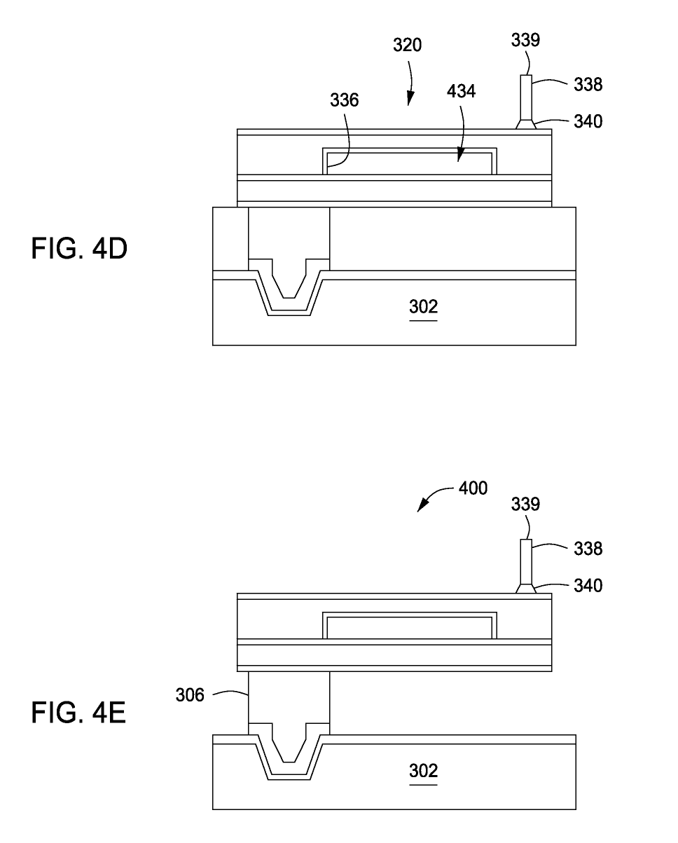

In addition, variation of the width W of the beam 102 may be selectively controlled in order to facilitate control of the spring constant of the resilient contact element 100 and/or performance characteristics of the resilient contact element 100. The variation of the width of the beam 302 may further be selectively controlled to form a geometry suitable for providing a plurality of resilient contact elements in an array having a first pitch proximate the tips of the resilient contact elements that is smaller than a pitch of a plurality of contact pads formed on a DUT, and a second pitch proximate the second ends of the beams to facilitate connection to a support, such as a probe card assembly, as discussed below with respect to FIG. 4. In some embodiments, the width of the second end 103 of the beam 102 can be about 2 or more times greater than the width of the first end 101 of the beam 102.

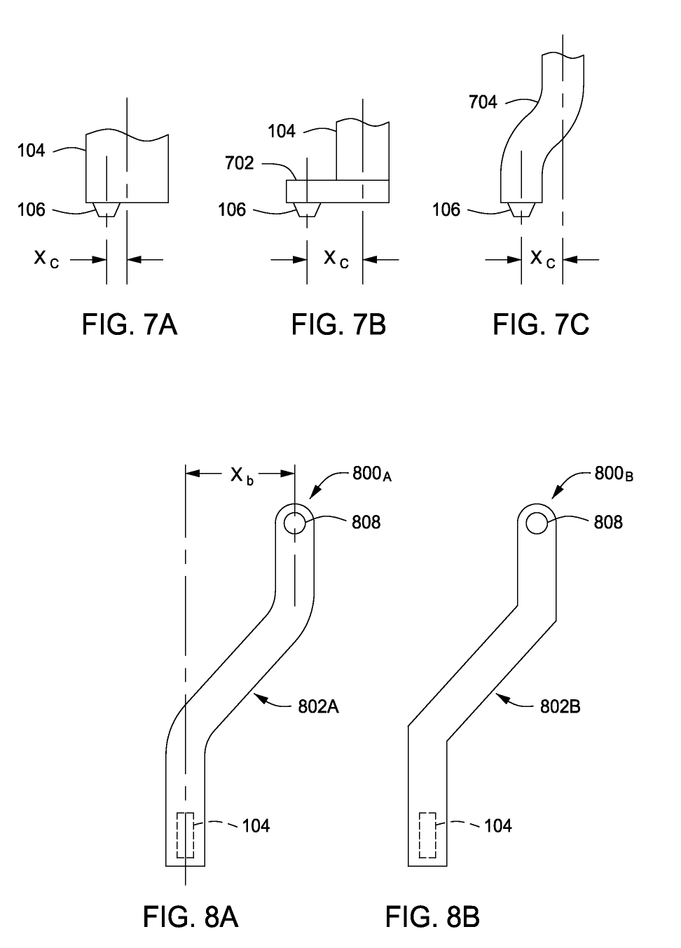

The tip 104 may include a contact 106 disposed on a distal portion of the tip 104. The tip 104 and/or the contact 106 are typically configured for contacting a device to be tested. The contact 106 may be positioned on the tip 104 to locate the contact 106 in a desired position suitable for contacting a terminal of a device to be tested or the like. The contact 106 may be disposed centrally on the tip 104 or may be offset in either or both of front-to-back or side-to-side orientations. For example, FIG. 7A depicts a partial front view of the tip 104 wherein the contact 106 is disposed to a side of the tip 104. The quantity of offset may be measured by a distance x_{c} (representing contact offset) measured between a central axis of the tip 104 and a central axis of the contact 106. Alternatively, and as shown in FIG. 7B, an offset member 702 may be disposed between the tip 104 and the contact 106 to facilitate a greater quantity of contact offset. Alternatively or in combination with either of the above, and as illustratively shown in FIG. 7C, a curved tip 704 may be coupled to the beam 102 instead of the tip 104 shown in FIG. 1. The contact 106 disposed on the end of the tip 704 has a contact offset defined by the amount of curvature of the tip 704. Alternatively or in combination with the side-to-side tip offset described above, a front-to-back tip offset may be provided in a similar manner.

Returning to FIG. 1, the tip 104 and/or the contact 106 may be fabricated from the same materials as the beam 102 or may be fabricated from different materials, thereby decoupling the contact requirements of the tip 104 and/or contact 106 from spring constant requirements of the beam 102. The tip 104 and/or contact 106 may comprise materials of suitable hardness and conductivity to provide the required contact with the DUT, as described above. In some embodiments, the tip 104 and/or contact 106 may be fabricated from noble metals and semi-noble metals, such as palladium, gold, rhodium, and combinations or alloys thereof (such as palladium cobalt, nickel palladium, or the like), and the like.

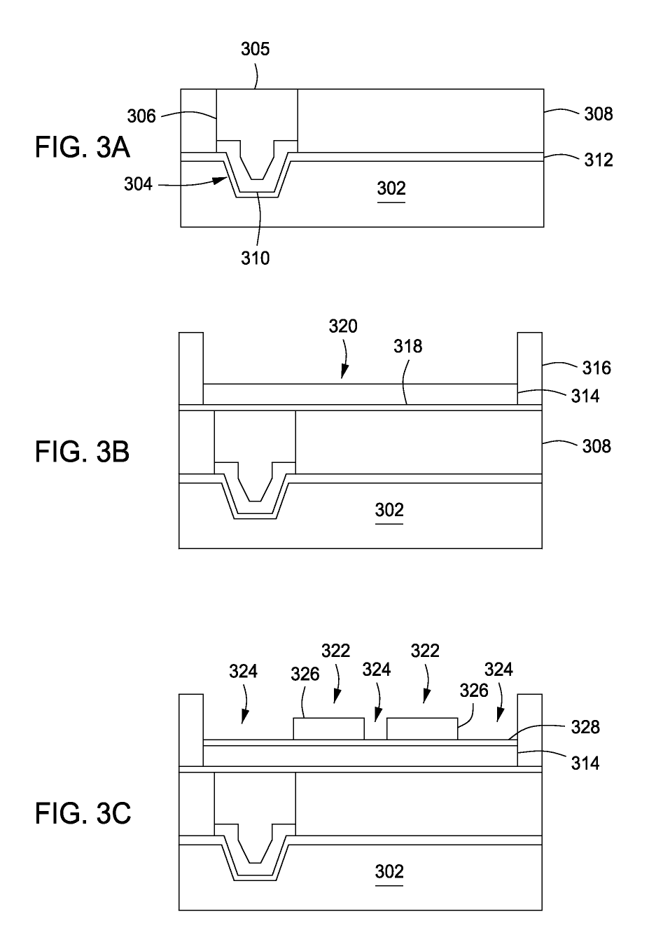

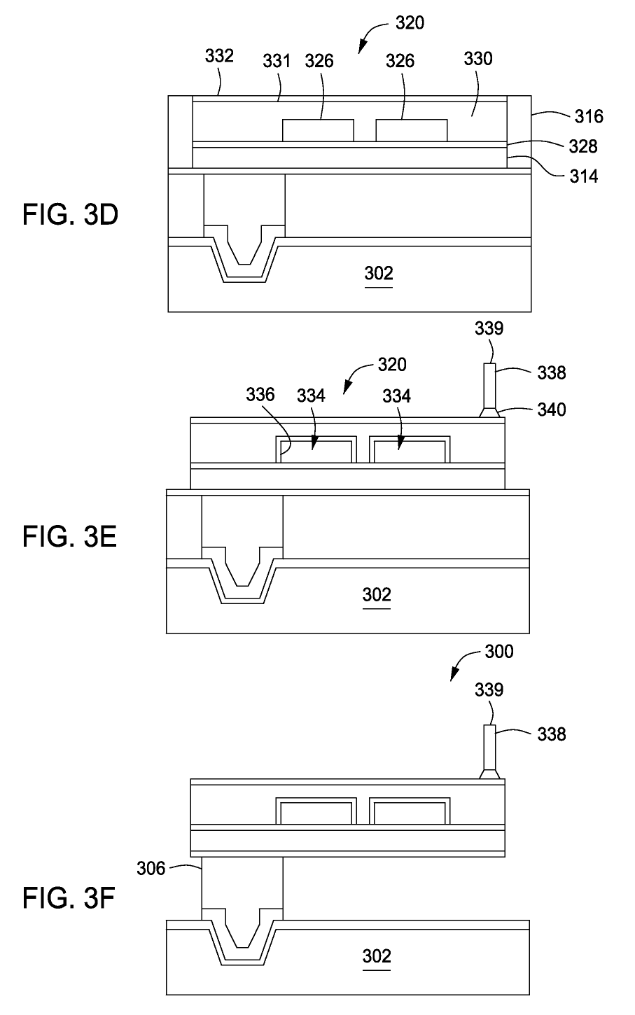

A post 108 may be coupled to the beam 102 proximate the second end 103. The post 108 is configured to support the resilient contact element 100 (for example to couple a resilient contact element to a probe card assembly, as discussed below with respect to FIGS. 3 and 4) and can provide an electrical pathway to facilitate electrical communication between the tip 104 and/or contact 106 and a test system (discussed in more detail below with respect to FIG. 4). Accordingly, the post 108 typically comprises a stiff, conductive material that has minimal or no deformation or deflection during operation (e.g., materials having a high Young's modulus). Examples of suitable materials include metals or metal coated materials. The post 108 may be formed and coupled to the beam 102 by any suitable method, such as by soldering, wirebonding and overplating, molding and electroplating, or the like.

The dimensions and materials described herein for the resilient contact element 100 are exemplary only. It is contemplated that resilient contact elements as described herein may have other dimensions or be made from alternate materials suited for particular applications in accordance with the teachings provided herein. For example, the dimensions of the resilient contact element may be selected to meet certain design characteristics, such as matching the pitch and geometrical configuration of contact pads on a DUT and generating sufficient contact force to establish reliable temporary electrical contact therewith.

For example, in some embodiments, the beam 102 of the resilient contact element 100 may be configured to provide a lateral offset between the first end of the beam 101 and the second end of the beam 103 (e.g., the beam 102 may be laterally non-linear, or non-linear along a major axis of the beam 102). FIGS. 8A-B depict respective top views of a resilient contact element 800_{A} and a resilient contact element 800_{B} in accordance with some embodiments of the invention. In the embodiment depicted in FIG. 8A, the resilient contact element 800_{A} includes a curved beam 800_{A}. The curved beam 802_{A} provides an offset between the tip 104 and a support post 808 (similar to support post 108 described below with respect to FIG. 1). The quantity of offset may be measured by a distance x_{b} (representing beam offset) measured perpendicularly between a central axis of the tip 104 (or, in some embodiments, a central axis of a contact disposed thereon) and a central axis of the post 808. Similarly, and as shown in FIG. 8B, a laterally angled beam may be utilized to provide the desired beam offset. The lateral offset described above may also be obtained by positioning the tip 104 (or a contact disposed thereon) laterally offset from a central axis of the beam (regardless of beam profile—straight, curved, angled, or combinations thereof). The shapes of the beams 802_{A}, 802_{B} are illustrative only and it is contemplated that other geometric shapes may be utilized to position the tips or contacts of the beams as desired including combinations of curved and angled shapes as well as varying widths along the length of the beam.

Moreover, a plurality of resilient contact elements having beams of similar or different shapes may be grouped together to form an array of resilient contact elements having a desired geometry. For example, FIG. 9 depicts an exemplary array of resilient contact elements 900 illustrating how a varied pitch of the tips and the support posts of the resilient contact elements may be controlled to facilitate providing a desired geometry. For example, the resilient contact elements 900 each comprise a beam 902 having a tip 904 disposed at a first end thereof and a support post 908 disposed at a second end thereof, the second end opposite the first end. Each beam 902 may be tapered towards the tips 904 to facilitate providing a closer spacing of the tips 904 than the posts 908. In some embodiments, a first pitch P₁ proximate tips 904 of the resilient contact elements 900 may be provided that corresponds to a desired configuration (such as corresponding to a plurality of contact pads formed on a DUT). A second pitch P₂ (greater than the first pitch P₁) may be provided proximate the posts 908 of the resilient contact elements 900 to facilitate connection, for example, to a probe card assembly (such as the probe card assembly discussed below with respect to FIG. 4). The configuration of the beams 902 (such as beam width, taper, angle or curvature of the beam, and the like) may be selectively controlled to provide the space transformation between the post connection pitch (P₂) and the contact pitch (P₁). Alternatively or in combination the configuration of the beams 902 (such as beam width, taper, and the like) may be selectively controlled to provide a desired spring constant for each beam. In some embodiments, one or more of the plurality of resilient contact elements having beams of similar or different shapes may be may be staggered.

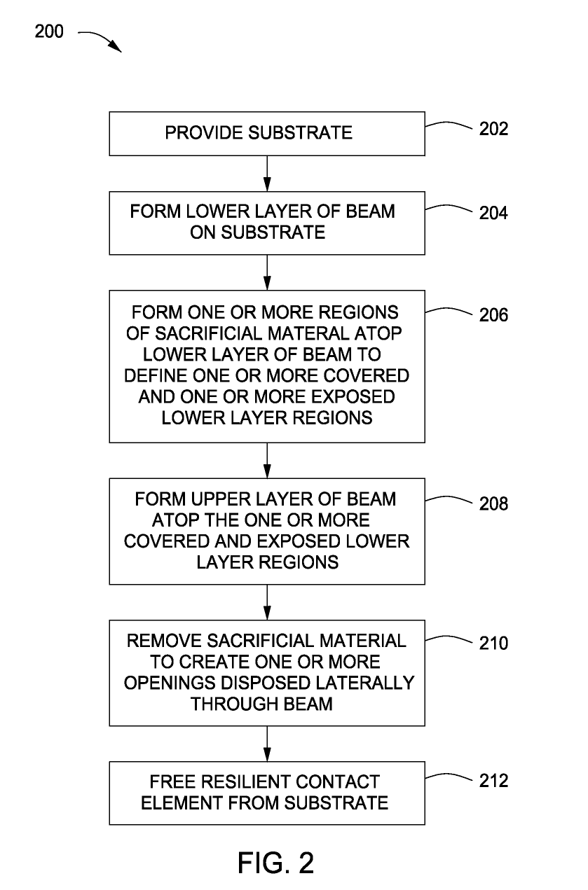

In addition to the inventive resilient contact elements described above, embodiments of the present invention further provide various fabrication processes for constructing the resilient contact elements. Fore example, FIGS. 2, 3A-F, and 4A-G respectively depict a process flow chart and illustrative stages of fabrication of a resilient contact element in accordance with some embodiments of the present invention. FIG. 2 depicts a process flow 200 for fabricating a resilient contact element 300 (as shown in FIGS. 3A-F) and, alternatively, a resilient contact element 400 (as shown in FIGS. 4A-G) according to some embodiments of the invention. Although the following discussion with respect to FIGS. 2-4 reflect the fabrication of a single resilient contact element, it is contemplated that a plurality of resilient contact elements may be simultaneously fabricated on a substrate utilizing any of the following methods.

The exemplary process 200 begins at 202 wherein a substrate 302 can be provided, as shown in FIG. 3A. The substrate may comprise any suitable substrate, and in some embodiments comprises silicon. The substrate may include a tip recess 304, which may be geometrically configured to correspond to a tip and/or contact to be formed on the resilient contact element. In some embodiments, the tip recess 304 may be formed in the substrate 302 by any suitable process, such as by depositing and patterning a photoresist layer upon the substrate 302 corresponding to the location of the tip recess and etching the tip recess 304 into the substrate 302. Although FIG. 3 illustrates one type of tip recess 304, other recess geometries for forming other types of tips may similarly be used in various embodiments of the invention.

In some embodiments, a tip 306 may be provided, for example by forming the tip 306 at least partially within the tip recess 304. A patterned mask layer 308 may be provided to define the tip 306. The patterned mask layer 308 may be formed in any suitable manner, such as by depositing and patterning a layer of dry film or liquid photoresist material atop the substrate 302. The tip 306 may include a contact 310 formed at a distal end thereof (e.g., within the tip recess 304). The tip 306 and/or the contact 310 are generally formed to a thickness suitable to ensure uniform coverage and, for example, to withstand operational contact and cleaning wear. For example, in a non-limiting example, a contact 310 may be provided having a thickness from between about 10 to 20 μm.

In some embodiments, prior to the formation of the tip 306 and/or contact 310, a tip seed layer 312 may be deposited over the substrate 302, including within the tip recess 304. Alternatively, the tip seed layer 312 may be deposited over the patterned mask layer 308 and into the tip recess 304. The tip seed layer 312 typically comprises a material that facilitates subsequent deposition of the material to be utilized to form the tip 306 and/or the contact 310 in the tip recess 304. The tip seed layer 312 may be deposited, for example, by chemical or physical vapor deposition (CVD or PVD), atomic layer deposition (ALD), or like methods. Non-limiting examples of suitable materials for the tip seed layer 312 include any conductive material or materials conducive to the plating process (e.g., conductive materials that provide a suitable plating finish).

The tip 306 and/or the contact 310 may be formed in any suitable manner, such as by plating or the like. Suitable non-limiting examples of materials which could be used for the tip 306 and/or the contact 310 include noble metals and semi-noble metals, such as palladium, gold, rhodium, and combinations or alloys thereof, and the like (as discussed above with respect to FIG. 1). In some embodiments, a contact 310 may be formed, for example, by plating a contact material over the substrate 302 (and over the tip seed layer 312, when present) into the tip recess 304 and subsequently forming, for example by plating, a tip 306 thereover. In some embodiments, the contact 310 may be formed from noble metals or semi-noble metals, and combinations or alloys thereof, such as rhodium, polonium-cobalt, or the like, and the tip 306 may be formed from a nickel-cobalt alloy. In some embodiments, an upper surface 305 of the tip 306 may be planarized, such as by lapping or other suitable process.

Next, at 204, a lower layer 314 of a beam 320 may be formed on the substrate, as shown in FIG. 3B. In some embodiments a lower layer 314 may be formed by depositing a material into an opening defined by a patterned mask layer 316. The patterned mask layer 316 may be formed atop the patterned mask layer 308 and may comprise similar materials and techniques for the fabrication thereof.

A beam seed layer 318 may be deposited over the patterned mask layer 308 and tip 306. The beam seed layer 318 typically comprises a material that facilitates subsequent deposition of the material to be utilized to form the lower layer 314 of the beam 320 and may be formed in a similar manner as discussed above with respect to forming the tip seed layer 312. In some embodiments, the beam seed layer 318 comprises gold. In one non-limiting example, the beam seed layer 318 comprises a layer of gold formed to a thickness of about 2 μm.

The lower layer 314 may be formed by depositing material within the patterned mask layer 316 and atop the beam seed layer 318 (when present) to a desired thickness. Although shown in cross-section, the mask layer 316 also defines the boundaries of the beam 320 along its length and may be configured to form a beam having a uniform or a tapered width, as discussed above with respect to FIG. 1, or of varying shapes, as discussed above with respect to FIGS. 8A-B. Suitable non-limiting examples of materials which could be used for the beam are discussed above with respect to the beam 102 shown in FIG. 1. In some embodiments, the lower layer 314 comprises a nickel-cobalt alloy.

Next, at 206, a sacrificial material 326 may be selectively formed atop the lower layer 314 of the beam 320 to define one or more covered regions 322 and one or more exposed regions 324 of the lower layer 314, as shown in FIG. 3C. The sacrificial material 326 may comprise a material that is substantially inert to the materials that form the beam 320 and the tip 306 and that may be removed without damaging the beam 320 and the tip 306. In some embodiments, as depicted in FIG. 3C, the sacrificial material 326 may comprise a photoresist material that may be suitably selectively formed (such as by spray coating, electrodepositing, or the like) to define the covered regions 322 and the exposed regions 324 of the lower layer 314.

Alternatively, and as depicted in FIGS. 4A-B, a sacrificial material 426 may be selectively formed atop the lower layer 314 of the beam 320 by first forming and patterning a material 402 (such as photoresist) to inversely define one or more covered regions 422 and one or more exposed regions 424 of the lower layer 314. A sacrificial material 426 may then be formed in the regions corresponding to the covered regions 422 defined by the patterned material 402 and the material 402 may be subsequently removed to positively define the covered and exposed regions 422, 424 of the lower layer 314. The material 402 may be removed by any suitable process, such as a wet resist stripping and plasma ashing process, or the like.

The sacrificial material 426 may comprise a material that is substantially inert to the materials that form the beam 320 and the tip 306 and that may be removed without damaging the beam 320 and the tip 306. In some embodiments, as depicted in FIG. 4B, the sacrificial material 426 may comprise a conductive material, such as a metal, that may be deposited into openings defined by the patterned material 402 by suitable selective methods, such as plating, or the like. In one non-limiting example, the sacrificial material 426 may comprise copper.

In some embodiments, and as depicted in both FIGS. 3C and 4A-B, a seed layer 328 may be deposited over the lower layer 314. The seed layer 328 typically comprises a material that facilitates subsequent deposition of the material to be utilized to form an upper layer of the beam 320 atop the lower layer 314 of the beam 320 and may be formed in a suitable selective manner, such as by plating. In embodiments where the sacrificial material is a conductive material (such as depicted in FIGS. 4A-B), the seed layer 328 may further facilitate the formation of the layer of sacrificial material. In some embodiments, the seed layer 328 comprises gold. In one non-limiting example, the seed layer 328 comprises a layer of gold formed to a thickness of about 2 μm.

Next, at 208, an upper layer 330 of the beam 320 may be formed atop the lower layer 314, as shown in FIG. 3D. Upper layer 430 may be similarly formed, as shown in FIG. 4C. In some embodiments the upper layer 330, 430 may be formed by depositing a material into the opening defined by the patterned mask layer 316 as discussed above at 204. The upper layer 330, 430 may be formed by depositing material within the patterned mask layer 316 and atop the seed layer 328 (when present) to a desired thickness. The upper layer 330, 430 may be formed by any suitable process, such as by plating. The upper layer 330, 430 may comprise any of the materials discussed above with respect to lower layer 314. The upper layer 330, 430 may be fabricated from the same or different materials as the lower layer 314. In some embodiments, the upper layer 330, 430 comprises a nickel-cobalt alloy.

In some embodiments, an upper surface 331 of the upper layer 330 or an upper surface 431 of the upper layer 430 may be planarized after being formed.

The upper layer 330, 430 may be planarized by any suitable process, such as lapping, chemical mechanical polishing (CMP), electrochemical mechanical polishing (ECMP), or the like.

In some embodiments, and as shown in FIGS. 3D and 4C, a cap layer 332, 432 may be formed atop the upper layer 330, 430 to provide protection from corrosion of the upper layer 330, 430. The cap layer 332, 432 may be formed of a suitable material for providing an improved interface for soldering or otherwise connecting a post to the upper layer 330, 430 (e.g., for improving adhesion therebetween, as discussed in more detail below), and/or for preventing or limiting corrosion and/or degradation of the electrical performance of the resilient contact element. In some embodiments, the cap layer 332, 432 may comprise gold. In embodiments, where the cap layer 332, 432 is provided, the upper layer 330, 430 may be planarized before or after formation of the cap layer 332, 432 thereupon.

Next, at 210, the sacrificial material 326, 426 may be removed to create one or more openings 334, 434 disposed laterally through the beam 320, as respectively depicted in FIGS. 3E and 4D. The sacrificial material may be removed in any suitable manner that does not damage the beam 320 or the tip 304 of the resilient contact element. For example, in embodiments where the sacrificial material 326 comprises a photoresist or like materials (as depicted in FIGS. 3A-F), the mask layer 316 and the sacrificial material 326 may be removed by a laser stripping process, a dry plasma process, or the like. In embodiments where the sacrificial material 426 comprises a metal, such as copper or like materials (as depicted in FIGS. 4A-E), the mask layer 316 may be removed as described above, and the sacrificial material 426 may be removed by a suitable dry plasma process such as a metal etch process or the like.

Optionally, the openings 334, 434 of the beam 320 may be coated with a material layer 336. The material layer 336 may increase conductivity of the resilient contact element and improve current to fail. The material layer 336 may also provide protection from corrosion of the exposed portions of the lower layer 314 and the upper layer 330, 430. The material layer 336 may be formed of a suitable material that provides for at least one of increasing conductivity of the resilient contact element, improving current to fail, or preventing or limiting corrosion and/or degradation of the electrical performance of the resilient contact element. In some embodiments, the material layer 336 may comprise gold. The material layer 336 may be formed by a suitable selective deposition process, such as plating or the like. To facilitate adhesion of the material layer 336 to the exposed portions of the lower layer 314 and the upper layer 330, 430, a field metal etch process may be first performed to prepare the exposed surfaces of the lower layer 314 and the upper layer 330, 430 in the openings 334, 434 for subsequent formation of the material layer 336. In one non-limiting embodiment, the exposed portions of the lower layer 314 and the upper layer 330, 430 are first etched and the material layer 336 subsequently formed by plating with gold.

In some embodiments, a post 338 may be affixed to an end of the beam 320 opposite the tip 304, as shown in FIGS. 3E and 4D. The post 338 may be affixed to the beam 320 in any suitable manner, such as by soldering, brazing, wire-bonding, molding, or the like. For example, in some embodiments, and as depicted in 3E and 4D, the post 338 may be affixed to the beam 320 by solder 340. Alternatively, a wire (not shown) may be bonded to the beam 320 and subsequently over-coated and planarized to form the post 338. Alternatively, a structure (not shown) may be molded onto the beam 320 and subsequently electroplated to form the post 338. It is contemplated that the post 338 may alternatively be affixed to the beam 320 subsequent to the removal of the resilient contact element from the substrate 302 utilizing any of the methods described above. Optionally, the post 338 may be coupled to a support substrate either prior to or after affixing the post 338 to the beam 320. The support substrate may be a temporary support for the post 338 or may be a component of a probe card assembly (such as the probe substrate 424 depicted in FIG. 4).

Next, at 212, the resilient contact element 300, 400 may be removed from the substrate 302. The resilient contact element 300, 400 may be removed from the substrate 302 by removing the mask layer 308 (using any suitable process, such as those described above with respect to removing the mask layer 316) and etching away, i.e., undercutting the tip 306 and/or the contact 310 and/or the tip seed layer 312 (when present), thus freeing the resilient contact element 300, 400 from the substrate 302. The substrate 302 may then be reused to form additional resilient contact elements 300, 400 by repeating one or more portions of the above process.

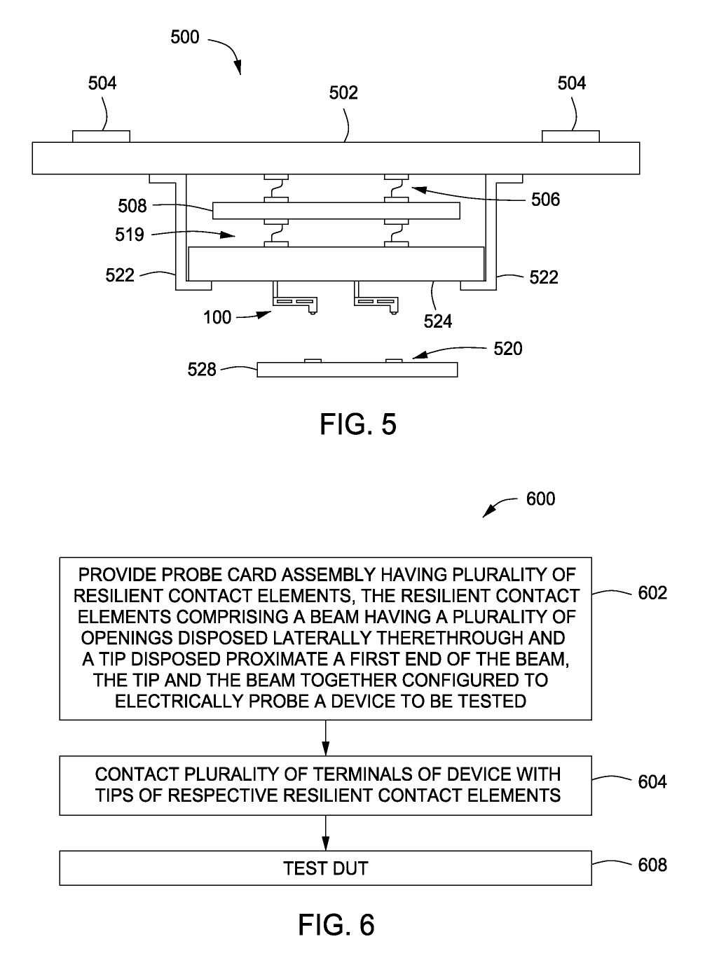

Portions of the above process flow may be altered, or may overlap, depending upon the attachment process utilized to couple the post 338 to the beam 320. For example, in some embodiments, after the sacrificial material 326, 426 is removed and, optionally, the openings 334, 434 are coated, the post 338 may be affixed to the beam 320 as described above. Subsequently, the mask layer 308 may be removed and the upper end 339 of the post 338 may be coupled to a substrate (not shown), such as a probe substrate as described in more detail below with respect to FIG. 5. Upon coupling the post 338 to the substrate (not shown), the tip 306 and/or the contact 310 and/or the tip seed layer 312 (when present) may be etched away, i.e., undercut, to free the resilient contact element 300, 400 from the substrate 302.

In some embodiments, after the sacrificial material 326, 426 is removed and, optionally, the openings 334, 434 are coated, the mask layer 308 may be removed as described above. Subsequently, a post 338 that is already has an upper surface 339 coupled to a substrate (not shown), such as a probe substrate as described in more detail below with respect to FIG. 5, may be affixed to the beam 320 as described above. Upon coupling the post 338 to the substrate (not shown), the tip 306 and/or the contact 310 and/or the tip seed layer 312 (when present) may be etched away, i.e., undercut, to free the resilient contact element 300, 400 from the substrate 302.

Upon release of the resilient contact element 300, 400 from the substrate 302, the resilient contact elements 300, 400 may be utilized, for example, as part of a probe card assembly for testing devices. For example, FIG. 5 depicts a schematic view of an illustrative probe card assembly 500 having one or more resilient contact elements 100 (similar to resilient contact elements 300, 500) as described herein according to some embodiments of the invention. The exemplary probe card assembly 500 illustrated in FIG. 5 can be used to test one or more electronic devices (represented by DUT 528). The DUT 528 can be any electronic device or devices to be tested. Non-limiting examples of a suitable DUT include one or more dies of an unsingulated semiconductor wafer, one or more semiconductor dies singulated from a wafer (packaged or unpackaged), an array of singulated semiconductor dies disposed in a carrier or other holding device, one or more multi-die electronics modules, one or more printed circuit boards, or any other type of electronic device or devices. The term DUT, as used herein, refers to one or a plurality of such electronic devices.

The probe card assembly 500 generally acts as an interface between a tester (not shown) and the DUT 528. The tester, which can be a computer or a computer system, typically controls testing of the DUT 528, for example, by generating test data to be input into the DUT 528, and receiving and evaluating response data generated by the DUT 528 in response to the test data. The probe card assembly 500 includes electrical connectors 504 configured to make electrical connections with a plurality of communications channels (not shown) from the tester. The probe card assembly 500 also includes one or more resilient contact elements 100 configured to be pressed against, and thus make electrical connections with, one or more input and/or output terminals 520 of DUT 528. The resilient contact elements 100 are typically configured to correspond to the terminals 520 of the DUT 528 and may be arranged in one or more arrays having a desired geometry.

The probe card assembly 500 may include one or more substrates configured to support the connectors 504 and the resilient contact elements 100 and to provide electrical connections therebetween. The exemplary probe card assembly 500 shown in FIG. 5 has three such substrates, although in other implementations, the probe card assembly 500 can have more or fewer substrates. In the embodiment depicted in FIG. 5, the probe card assembly 500 includes a wiring substrate 502, an interposer substrate 508, and a probe substrate 524. The wiring substrate 502, the interposer substrate 508, and the probe substrate 524 can generally be made of any type of suitable material or materials, such as, without limitation, printed circuit boards, ceramics, organic or inorganic materials, and the like, or combinations thereof.

Electrically conductive paths (not shown) may be provided from the connectors 504 through the wiring substrate 502 to a plurality of electrically conductive spring interconnect structures 506. Other electrically conductive paths (not shown) may be provided from the spring interconnect structures 506 through the interposer substrate 508 to a plurality of electrically conductive spring interconnect structures 519. Still other electrically conductive paths (not shown) may further be provided from the spring interconnect structures 519 through the probe substrate 524 to the resilient contact elements 100. The electrically conductive paths through the wiring substrate 502, the interposer substrate 508, and the probe substrate 524 can comprise electrically conductive vias, traces, or the like, that may be disposed on, within, and/or through the wiring substrate 502, the interposer substrate 508, and the probe substrate 524.

The wiring substrate 502, the interposer substrate 508, and the probe substrate 524 may be held together by one or more brackets 522 and/or other suitable means (such as by bolts, screws, or other suitable fasteners). The configuration of the probe card assembly 500 shown in FIG. 5 is exemplary only and is simplified for ease of illustration and discussion and many variations, modifications, and additions are contemplated. For example, a probe card assembly may have fewer or more substrates (e.g., 502, 508, 524) than the probe card assembly 500 shown in FIG. 5. As another example, a probe card assembly may have more than one probe substrate (e.g., 524), and each such probe substrate may be independently adjustable. Non-limiting examples of probe card assemblies with multiple probe substrates are disclosed in U.S. patent application Ser. No. 11/165,833, filed Jun. 24, 2005. Additional non-limiting examples of probe card assemblies are illustrated in U.S. Pat. No. 5,974,662, issued Nov. 2, 1999 and U.S. Pat. No. 6,509,751, issued Jan. 21, 2003, as well as in the aforementioned U.S. patent application Ser. No. 11/165,833. It is contemplated that various features of the probe card assemblies described in those patents and application may be implemented in the probe card assembly 500 shown in FIG. 5 and that the probe card assemblies described in the aforementioned patents and application may benefit from the use of the inventive resilient contact elements disclosed herein. FIG. 5 depicts just one illustrative example of the types of probe card assemblies that may incorporate resilient contact elements as described herein and many other probe card assemblies having various configurations are within the scope of this invention.

FIG. 6 depicts an illustrative process 600 for testing a DUT with a probe card assembly having resilient contact elements according to some embodiments of the invention. The process 600 can be described with respect to the probe card assembly 500 described above with respect to FIG. 5 and the resilient contact element 100 described above with respect to FIG. 1. The method 600 begins at 602, where a probe card assembly 500 is provided. The probe card assembly 500 has a plurality of resilient contact elements disposed thereon for testing the DUT. At least one of the resilient contact elements is a resilient contact element 100 (or resilient contact elements 300, 400 or variants thereof, as described herein). For example, the resilient contact elements 100 may comprise a lithographically formed resilient beam 102 having a plurality of openings 110 disposed laterally therethrough and a tip 104 disposed proximate a first end 101 of the beam 102. The tip 104 and the beam 102 are configured to electrically probe a device to be tested (e.g., DUT 528). The DUT 528 may generally be disposed upon a movable support within a test system (not shown).

Next, at step 602, the terminals 520 of the DUT 528 are brought into contact with the tips 104 (or the contacts 106 disposed thereon) of the resilient contact elements. The resilient contact elements can be brought into contact with the terminals 520 of the DUT 528 by moving at least one of the DUT 528 or the probe card assembly 500. Typically, the DUT 528 is disposed on a movable support disposed in the test system (not shown) that moves the DUT 528 into sufficient contact with the resilient contact elements to provide reliable electrical contact with the terminals 520.

When moving the DUT 528 to contact the resilient contact elements of the probe card assembly 500, the DUT 528 typically continues to move towards the probe card assembly 500 until all of the resilient contact elements 100 come into sufficient electrical contact with the terminals 520. Due to any non-planarity of the respective tips of the resilient contact elements 100 disposed on the probe card assembly 500 and/or any non-planarity of the terminals 520 of the DUT 528, the DUT 528 may continue to move towards the probe card assembly 500 for an additional distance after the initial contact of the first resilient contact element to suitably contact each of the terminals 520 of the DUT 528 (sometimes referred to as overtravel). In a non-limiting example, such a distance could be about 1-4 mils (about 25.4-102 μm). Accordingly, some of the resilient contact elements may undergo more deflection than others. However, the resilient contact elements described herein can advantageously provide a reduced scrub along the terminals 520 while still providing suitable contact forces to establish a reliable electrical connection suitable for testing (e.g., to break through any oxide layers present on the terminals 520 of the DUT 528, or to otherwise establish and maintain suitable electrical connection). The reduced scrub distance traveled advantageously facilitates testing of higher feature density devices with reduced risk of mis-probes by maintaining proper alignment with and contact to the devices and reduced risk of damage to the probing pad area on the DUT that may be caused by excessive scrub.

Once contact is made, the DUT 528 may be tested per a pre-determined protocol, for example, as contained in the memory of the tester. For example, the tester may generate power and test signals that are provided through the probe card assembly 500 to the DUT 528. Response signals generated by the DUT 528 in response to the test signals are similarly carried through the probe card assembly 500 to the tester, which may then analyze the response signals and determine whether the DUT 528 responded correctly to the test signals. Upon completion of testing, the method ends.

Thus methods and apparatus suitable for testing devices having reduced feature sizes (e.g., under 50 microns), and methods for fabricating same, have been provided herein. The inventive apparatus and methods facilitate testing of such devices with reduced incidence of damage to the resilient contact elements utilized to contact the devices. The inventive apparatus further advantageously provides a reduced scrub as compared to conventional cantilevered contact elements. The reduced scrub may further advantageously reduce damage to the probing pad area on the DUT.

While the foregoing is directed to embodiments of the present invention, other and further embodiments of the invention may be devised without departing from the basic scope thereof, and the scope thereof is determined by the claims that follow.

1. A resilient contact element, comprising:
a lithographically formed resilient beam having a plurality of openings disposed laterally therethrough; and
a tip disposed proximate a first end of the beam, the tip and the beam together configured to electrically probe a device to be tested.

2. The resilient contact element of claim 1, wherein a lower scrub ratio is provided as compared to solid cantilevered beam contact element.

3. The resilient contact element of claim 1, wherein the contact is laterally offset from the beam.

4. The resilient contact element of claim 1, wherein a width of the beam tapers towards the tip.

5. The resilient contact element of claim 1, wherein a width of the beam varies towards the tip to achieve a desired spring constant.

6. The resilient contact element of claim 1, wherein the beam is laterally non-linear.

7. A probe card assembly for testing a semiconductor device, comprising:
a probe substrate; and
at least one resilient contact element coupled to the probe substrate, the resilient contact element comprising:
a lithographically formed resilient beam having a plurality of openings disposed laterally therethrough; and
a tip disposed proximate a first end of the beam, the tip and the beam together configured to electrically probe a device to be tested.

8. The probe card assembly of claim 7, wherein a lower scrub ratio is provided as compared to solid cantilevered beam contact element.

9. The probe card assembly of claim 7, wherein the contact is laterally offset from the beam.

10. The probe card assembly of claim 7, wherein a width of the beam tapers towards the tip.

11. The resilient contact element of claim 1, wherein a width of the beam varies towards the tip to achieve a desired spring constant.

12. The probe card assembly of claim 7, wherein the beam is laterally non-linear.

13. A method of fabricating a resilient contact element, comprising:
a) forming a lower layer of a beam upon a substrate;
b) forming one or more regions of sacrificial material atop one or more portions of the lower layer of the beam to define one or more covered regions of the lower layer and one or more exposed regions of the lower layer;
c) forming an upper layer of the beam atop the one or more exposed regions of the lower layer and the one or more covered regions of the lower layer to define the beam; and
d) removing the one or more regions of sacrificial material to create one or more openings disposed laterally through the beam.

14. The method of claim 13, wherein the sacrificial material is photoresist.

15. The method of claim 13, wherein the sacrificial material is copper.

16. The method of claim 15, further comprising:
forming and patterning a mask layer to define one or more regions where the copper sacrificial material is to be formed.

17. The method of claim 13, further comprising:
forming a tip in the substrate prior to forming the lower layer of the beam thereover.

18. The method of claim 17, wherein the tip comprises different materials than the beam.

19. The method of claim 13, wherein a plurality of beams are formed on the substrate.

20. The method of claim 13, wherein forming the lower layer comprises:
depositing and patterning a resist layer; and
plating a beam material within the patterned resist layer.

21. The method of claim 20, wherein forming the upper layer comprises:
plating a beam material within the patterned resist layer.

22. The method of claim 13, further comprising:
planarizing the upper layer.

23. The method of claim 13, further comprising:
forming a layer of gold on top of the upper layer.

24. The method of claim 13, further comprising:
forming a layer of gold on the sides of the upper layer and lower layer of the beam and within the openings disposed laterally therethrough.

25. A method of testing a device, comprising:
providing a probe card assembly comprising a probe substrate having a plurality of resilient contact elements coupled thereto, at least one resilient contact element comprising a lithographically formed resilient beam having a plurality of openings disposed laterally therethrough, and a tip disposed proximate a first end of the beam, the tip and the beam together configured to electrically probe a device to be tested; and
contacting a plurality of terminals of the device with the tips of respective resilient contact elements.

26. The method of claim 25, wherein the step of contacting further comprises:
moving at least one of the probe card assembly or the device to establish an initial contact between the plurality of terminals of the device and the tips of the resilient contact elements; and
further moving at least one of the probe card assembly or the device to establish a desired contact pressure between the plurality of terminals of the device and respective tips of the contact elements.

27. The method of claim 26, wherein the tips of the resilient contact elements have a reduced scrub as compared to solid cantilevered beam contact elements.

28. The method of claim 25, further comprising:
providing one or more electrical signals to at least one terminal of the device to be tested through the probe card assembly.

29. A semiconductor device tested by a method comprising:
providing a probe card assembly comprising a probe substrate having a plurality of resilient contact elements coupled thereto, at least one resilient contact element comprising a lithographically formed resilient beam having a plurality of openings disposed laterally therethrough, and a tip disposed proximate a first end of the beam, the tip and the beam together configured to electrically probe a device to be tested; and
contacting a plurality of terminals of the device with the tips of respective resilient contact elements.

30. The method of claim 29, wherein the step of contacting further comprises:
moving at least one of the probe card assembly or the device to establish an initial contact between the plurality of terminals of the device and the tips of the resilient contact elements; and
further moving at least one of the probe card assembly or the device to establish a desired contact pressure between the plurality of terminals of the device and respective tips of the contact elements.

31. The method of claim 30, wherein the tips of the resilient contact elements have a reduced scrub as compared to solid cantilevered beam contact elements.

32. The method of claim 29, further comprising:
providing one or more electrical signals to at least one terminal of the device to be tested through the probe card assembly.

33-60. (canceled)
